(19) United States
(12) Patent Application Publication
(10) Pub. No.: US 2026/0168651 A1
(43) Pub. Date: Jun. 18, 2026

(54) SYSTEM AND METHOD FOR POSITIONING A REFLECTOR ON PRINTED CIRCUIT BOARD

(71) Applicant: Valeo Vision, Bobigny (FR)

(72) Inventors: Colby DARLAGE, Seymour, IN (US); Robert FRAIZER, Seymour, IN (US); Brian GUINN, Seymour, IN (US); Paul TRUE, Seymour, IN (US)

(73) Assignee: Valeo Vision, Bobigny (FR)

(21) Appl. No.: 18/984,611

(22) Filed: Dec. 17, 2024

(51) Int. Cl. F21V 17/06

(52) U.S. Cl. CPC F21V 17/06; F21S 41/147; F21S 41/148; F21S 41/39; F21S 41/55; F21V 17/005; H05K 1/0266; H05K 2201/09918

(57) ABSTRACT

The present invention relates to precise positioning of a reflector unit on a printed circuit board. The printed circuit board includes reference mark(s) provided at predefined relative location(s) and/or orientation(s) with respect to light source(s). The reflector unit includes positioning hole(s) formed at predefined relative location(s) and/or orientation(s) with respect to reflective portion(s). The positioning hole(s) of the reflector unit corresponds to the reference mark(s) of the printed circuit board. The reference mark is properly aligned with the corresponding positioning hole to properly position the reflector unit on the printed circuit board. A detection unit is used to detect, monitor, and verify the alignment between the reference mark and the positioning hole. The proper alignment of the reference mark with the corresponding positioning hole ensures precise relative positioning of the light source with the corresponding reflective portion.

### TECHNICAL FIELD

The present invention relates to a system and method for precise positioning of lighting components in motor vehicles. Specifically, the invention addresses the challenge of ensuring accurate alignment between a reflector unit and a printed circuit board (PCB) in automotive lighting devices

### BACKGROUND OF THE INVENTION

Modern automotive lighting devices, such as headlamps and tail lamps, are increasingly compact, requiring smaller reflector units with shorter focal lengths. The precise positioning of light sources on the PCBA relative to the reflector unit is critical to achieving the desired beam pattern. Even minor variations in their relative positions can significantly affect the light output.

Conventional datum technologies utilize locator pins on the reflector unit, which engage with corresponding holes on the PCBA. However, manufacturing tolerances in the assembly process can lead to inaccuracies in the relative positioning of the reflector and the light source. Further, once assembly is done it is not possible to verify that the light sources of the PCBA are properly aligned with the reflector in a desired way.

The prior art and the convention datum technologies or positioning systems have various disadvantages as described above and there is a need for a precise positioning system for vehicle lighting device, that can overcome the disadvantages of the conventional positioning systems.

### SUMMARY OF THE INVENTION

An object of the present invention is to solve the disadvantages described above of known positioning system(s). In particular, an object of the present invention is to provide positioning system that ensures precise positioning of the reflector unit in relation to the light source(s).

Another object of the present invention is to provide precise positioning system for assembly of a reflector unit and a printed circuit board (PCB) to improve beam pattern accuracy and consistency.

Yet another object of the present invention is to provide a method of assembly for mounting a reflector unit on a PCB, the method including positioning of the reflector unit with respect to the PCB.

In this context, the present invention is directed towards printed circuit board including a substrate, at least one light source, and at least one reference mark. The at least one light source may be mounted on the substrate. Preferably, plurality of light sources may be arranged on the substrate in a predefined configuration. The at least one reference mark may be provided on the substrate at a predefined location and orientation with respect to the at least one light source. Preferably, plurality of reference marks may be provided relative to the plurality of light sources. The at least one reference mark may be adapted to be aligned with a corresponding positioning hole formed on a reflector unit. During assembly of the printed circuit board with the reflector unit, the reference marks may be aligned with corresponding positioning holes of the reflector unit to achieve proper positioning. The proper/desired positioning between the printed circuit board and the reflector unit may improve the accuracy of the relative position of the light source with a reflective portion to achieve desired light beam.

In a non-limiting embodiment of the present invention, the at least one reference mark may include a circle having a predefined diameter. Moreover, the diameter of the circle may be less than the diameter of the corresponding positioning hole, so that the circle may be accommodated within outline of the corresponding positioning hole of the reflector unit while positioning the reflector unit on the printed circuit board.

In a non-limiting embodiment of the present invention, the at least one reference mark may include at least one line or a polygon having predefined dimensions. Preferably, the reference mark may include plurality of lines provided in predefined arrangement such as cross-lines to form cross mark etc. Alternatively, the reference mark may include triangle, rectangle, or any other polygon having vertices which may be aligned with corresponding alignment features provided around the positioning hole, to ensure angular alignment of the reference mark with the corresponding positioning hole.

In a non-limiting embodiment of the present invention, the at least one reference mark may be provided on the substrate by laser printing, screen printing, painting, embossing, or pasting a sticker. However, reference mark may be formed on the printed circuit board by any other means such that the reference mark may be distinguishable from the other portion of the substrate.

In a non-limiting embodiment of the present invention, the at least one reference mark may be integrally formed on the substrate.

In a non-limiting embodiment of the present invention, the at least one reference mark may have a predefined color. The color of the reference mark may be different from the color of the printed circuit board to improve accuracy of detection of the reference mark by a camera/detection unit or by human eyes.

The present invention also relates to a sub-assembly for a lighting device. The sub-assembly may include a reflector unit and a printed circuit board. The reflector unit may have at least one reflective portion. Preferably, plurality of reflective portions may be formed on the reflector unit in a predefined configuration. The printed circuit board may include at least one light source. Preferably, plurality of light sources such as but not limited to light emitting diode (LED) etc. corresponding to the reflective portions of the reflection unit, may be provided. The reflector unit may be mounted on the printed circuit board. The reflector unit may be arranged on the printed circuit board such that the light sources may be positioned relative to the reflective portion in a desired configuration. The printed circuit board may include at least one reference mark provided at a predefined location and orientation with respect to the at least one light source. Preferably, plurality of reference marks may be provided at predefined locations and orientations on the printed circuit board. The reflector unit may include at least one positioning hole formed at a predefined location and orientation with respect to the at least one reflective portion. The positioning hole may have any predefined shape of cross-section such as circle, polygon, cross-shaped etc. Preferably, plurality of positioning holes may be formed at predefined locations and orientations with respect to the reflective portions. The at least one positioning hole of the reflector unit may correspond to the at least one reference mark of the printed circuit board. When the reflector unit is positioned on the printed circuit board in desired relative position, the reference marks may be aligned with the corresponding positioning hole. More preferably, the reference marks of the printed circuit board may be aligned with the corresponding positioning holed to properly position the reflective portions of the reflector unit relative to the light sources of the printed circuit board.

In a non-limiting embodiment of the present invention, the at least one reference mark may be aligned with the corresponding positioning hole of the reflector unit. The alignment may include positioning the reference mark in the outline of the positioning hole in a desired angular orientation to achieve the desired precise positioning of the reflector unit on the printed circuit board.

In a non-limiting embodiment of the present invention, the at least one reference mark may include a circle having a predefined diameter. Moreover, the diameter of the circle may be less than the diameter of the corresponding circular positioning hole, so that the circle may be accommodated within outline of the corresponding circular positioning hole of the reflector unit while positioning the reflector unit on the printed circuit board.

In a non-limiting embodiment of the present invention, the at least one reference mark may include at least one line or a polygon having a predefined dimensions. Preferably, the reference mark may include plurality of lines provided in predefined arrangement such as cross-lines to form cross mark etc. Alternatively, the reference mark may include triangle, rectangle, or any other polygon having vertices.

In a non-limiting embodiment of the present invention, the reflector unit may further include at least one alignment feature provided on the periphery of the positioning hole. Preferably, plurality of alignment features may be provided uniformly around the periphery of the positioning hole. The alignment feature may include triangle, circle, any other polygon, lines normal to the circumference of the positioning hole, or any other arrangement of lines. The alignment features may enable precise angular alignment of the reflector unit with respect to the printed circuit board by aligning the alignment feature with corresponding reference mark.

In a non-limiting embodiment of the present invention, the at least one alignment feature may complement the at least one reference mark provided on the printed circuit board.

In a non-limiting embodiment of the present invention, the at least one alignment feature may be provided on the reflector unit by laser printing, screen printing, painting, embossing, pasting a sticker, or integrally forming on the reflector unit. However, the alignment feature may be formed on the reflector unit by any other means such that the alignment feature may be distinguishable from the other portion of the reflector unit.

In a non-limiting embodiment of the present invention, the at least one alignment feature may have a predefined color. The color of the alignment feature may be different from the color of the reflector unit to improve accuracy of detection of the alignment feature by the camera/detection unit or by human eyes. Further, the color of the alignment feature may correspond to the color of the corresponding reference mark to improve detection of angular alignment.

In a non-limiting embodiment of the present invention, the at least one reference mark may be provided on the substrate by laser printing, screen printing, painting, embossing, pasting a sticker, or integrally forming the substrate. However, reference mark may be formed on the printed circuit board by any other means such that the reference mark may be distinguishable from the other portion of the substrate.

In a non-limiting embodiment of the present invention, the at least one reference mark may have a predefined color. The color of the reference mark may be different from the color of the printed circuit board to improve accuracy of detection of the reference mark by a camera/detection or by human eyes.

The present invention also relates to a method of assembling a reflector unit on a printed circuit board. The method may include providing a printed circuit board including at least one reference mark provided at a predefined location and orientation with respect to at least one light source. The printed circuit board may include plurality of reference marks provided relative to plurality of light sources. The method may further include providing a reflector unit including at least one positioning hole formed at a predefined location and orientation with respect to at least one reflective portion. The reflector unit may include plurality of positioning holes formed relative to the plurality of the reflective portions. The method may further include placing the reflector unit on the printed circuit board or vice versa. The method may further include positioning the reflector unit on the printed circuit board by aligning the reference mark with the corresponding positioning hole. The reflector unit may be positioned on the printed circuit board such that the light sources may be positioned at desired precise position relative to the corresponding reflective portions. The method may further include securing the reflector unit to the printed circuit board.

In a non-limiting embodiment of the present invention, positioning the reflector unit on the printed circuit board may include detecting and monitoring alignment of the at least one reference mark with the corresponding positioning hole by a detection unit. The detection unit may include a camera to detect the alignment between the reference mark with corresponding positioning hole to determine whether the reflector is precisely positioned on the printed circuit board or not.

In a non-limiting embodiment of the present invention, positioning the reflector unit on the printed circuit board may include readjusting the relative position and/or orientation of the reflector unit with respect to the printed circuit board till the desired alignment of the reference mark with the corresponding positioning hole is achieved and verified by the detection unit. When the detection unit determines misalignment between the reference mark and the corresponding positioning hole, the detection unit may suggest corrective relative movement and/or corrective relative rotation between the reflector unit and the printed circuit board, required to achieve the desired alignment.

In a non-limiting embodiment of the present invention, positioning the reflector unit on the printed circuit board may include capturing an image of the printed circuit board before placing the reflector unit on the printed circuit board, for detecting the relative position and orientation of the reference mark with respect to the at least one light source to determine the desired alignment of the reference mark with the positioning hole. The detection unit may determine the relative position and orientation of the reference mark(s) with respect to the light source(s) based on the captured image and may further determine or update the predefined acceptable alignment configuration of the reference mark with the corresponding positioning hole.

### BRIEF DESCRIPTION OF DRAWINGS

The present invention is expounded in detail below with the aid of the presented drawings. Items shown in the drawings are not to scale and are simplified to increase clarity of disclosure. In the drawings:

FIG. 1A illustrates a schematic isometric view of a lighting device, according to an embodiment of present invention;

FIG. 1B illustrates an exploded view of the lighting device, according to an embodiment of present invention;

FIG. 2 illustrates a schematic top view of a reflector unit, according to an embodiment of present invention;

FIG. 3 illustrates a schematic top view of a printed circuit board, according to an embodiment of present invention;

FIG. 4A illustrates a schematic top view of a sub-assembly of the reflector unit and the printed circuit board, according to an embodiment of present invention;

FIG. 4B illustrates a schematic isometric view of the sub-assembly with a detection unit, according to an embodiment of present invention;

FIGS. 5A, 5B, 5C, and 5D illustrate a portion of the sub-assembly, according to different embodiments of present invention; and

FIG. 6 illustrates a flowchart of a method of assembling the reflector unit on the printed circuit board, according to an embodiment of present invention.

### DETAILED DESCRIPTION OF THE INVENTION

The characteristics, variants and different modes of realization of the invention may be associated with each other in various combinations, in so far as they are not incompatible or exclusive with each other. In particular, variants of the invention comprising only a selection of features subsequently described in from the other features described may be imagined, if this selection of features is enough to confer a technical advantage and/or to differentiate the invention from prior art.

Items shown in the drawings may not be to the scale and are simplified to increase clarity of disclosure.

In the following description, the expression, “location” may be understood as point(s) in X-Y plane and the expression “orientation” may be understood as angular arrangement about the Z axis.

The present invention relates to a printed circuit board, a sub-assembly of a printed circuit board and a reflector unit, and a method of assembling the reflector unit on the printed circuit board. Present invention enables precise positioning between the reflector unit and the printed circuit board during assembly. The precise positioning between the reflector unit and the printed circuit board may improve accuracy with which the light source(s) provided on the printed circuit board may be positioned with respect to the corresponding reflective portion(s) of the reflector unit. The printed circuit board may include at least one reference mark provided at a predefined location and orientation with respect to at least one light source. The reflector unit may include at least one positioning hole formed at a predefined location with respect to at least one reflective portion. The reference mark may complement the corresponding positioning hole. For proper positioning of the reflector unit on the printed circuit board, the reference mark(s) may be aligned with the corresponding positioning hole(s) in a desired configuration. A detection unit including a camera may be used to detect, monitor, and verify the alignment between the reference mark and the corresponding hole. In case the detection unit detects misalignment, the reflector unit may need to be moved and/or rotated with respect to the printed circuit board to achieve desired alignment. Once the detection unit verifies that the desired alignment between the reflector unit and the printed circuit board is achieved, the reflector unit may be secured to the printed circuit board to form the sub-assembly which may be incorporated in a vehicle lighting device. This advantageously improves the positioning of the reflector unit on the printed circuit board to improve accuracy with which the light source may be positioned with respect to the reflective portion.

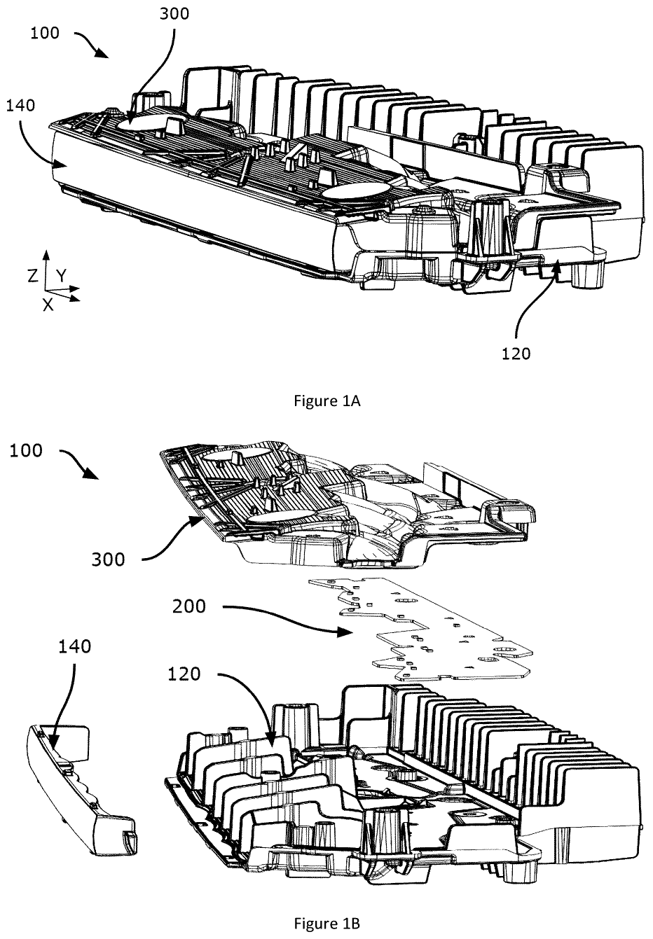

FIGS. 1A and 1B illustrate a lighting device 100 according to an exemplary embodiment of the present invention. The lighting device 100 may include a heatsink structure 120 supporting a printed circuit board 200, an optical lens unit 140, and a reflector unit 300. The printed circuit board 200 may be secured to the heatsink structure 120 in a predefined configuration by any of known means such as but not limited to clamping, screwing, bolting etc. The reflector unit 300 may also be secured to the heatsink structure 120 and/or the printed circuit board 200 by any suitable securing means. The reflector unit 300 and the printed circuit board 200 may be arranged on the heatsink structure 120 in such a manner that desired relative positioning and/or orientation of the reflector unit 300 with respect to the printed circuit board 200 is achieved. Further, the optical lens unit 140 may be arranged on the heatsink structure 120 and/or the reflector unit 300 in a desired configuration, as shown in FIG. 1A. It is to be noted that FIGS. 1A and 1B show only the exemplary configuration of the lighting device 100. However, present invention may also be realized for the lighting device 100 with various different configurations. Moreover, the lighting device 100 may also include other suitable components not listed here, which may be required for functioning of the lighting device 100.

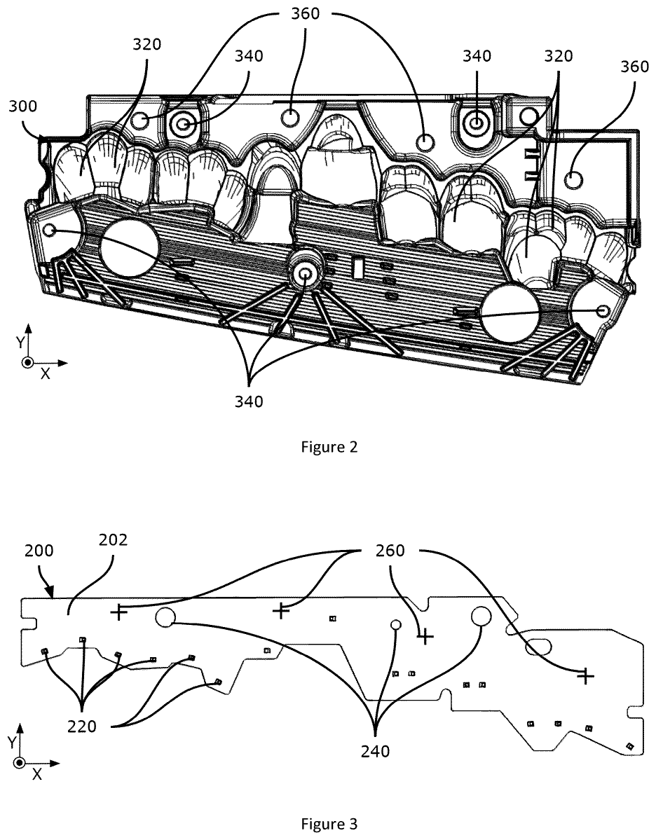

FIG. 2 shows a top view of the reflector unit 300, according to an embodiment of the present invention. The reflector unit 300 may include at least one reflective portion 320 adapted for receiving light from light source(s) and reflecting the incident light towards the optical lens unit 140. Plurality of reflective portions 320 may be formed in a desired arrangement as shown in FIG. 2. Preferably, each of the reflective portion 320 may include reflective surface(s) formed therein. The reflector unit 300 may further include mounting holes 340 adapted to receive a securing means such as screw to secure the reflector unit 300 to the heatsink structure 120. Moreover, the reflector unit 300 may include at least one positioning hole 360 formed at predefined location and orientation. Preferably, the positioning hole 360 may be a through hole formed on suitable portion of the reflector unit 300. The cross-section of the positioning hole 360 may be any of circular, elliptical, triangular, polygonal, cross-shaped, or any other suitable shape. The positioning hole 360 may be formed at a predefined relative location and/or relative orientation with respect to at least one of the reflective portions 320. The relative location of the positioning hole 360 from the reflective portion(s) 320 may be defined by linear distance measured along the X axis and the Y axis between the center of the positioning hole 360 and a fixed point on the reflective portion 320. Preferably, the relative location of the positioning hole 360 may be predefined with respect to multiple reflective portions 320 of the reflector unit 300. Further, the orientation of the positioning hole 360 may be defined in terms of relative angular position of the positioning hole 360 about the Z axis, in X-Y plane. Preferably, plurality of positioning holes 360 may be formed on the reflector unit 300 at predefined locations and in predefined orientations with respect to plurality of reflective portions 320. The reflector unit 300 may have a predefined color or metallization at least near the positioning holes 360 such that the edge(s) of the positioning hole(s) 360 may be detected by the detection unit with improved accuracy.

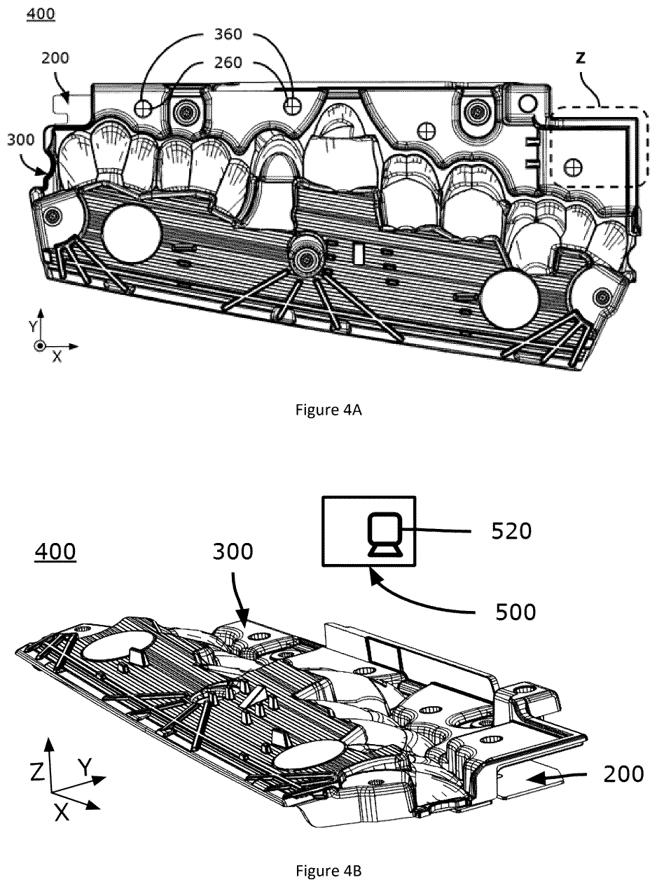

FIG. 3 shows a top view of the printed circuit board 200, according to an embodiment of the present invention. The printed circuit board 200 may include a substrate 202 having predefined thickness and shape. The printed circuit board 200 may further include mounting holes 240 formed at predefined locations on the substrate 202 for securing the printed circuit board 200 to the heatsink structure 120 and/or to the reflector unit 300 directly or indirectly. The mounting holes 240 of the printed circuit board 200 may correspond to some of the mounting holes 340 of the reflector unit 300, such that the printed circuit board 200 may be sandwiched between the reflector unit 300 and the heatsink structure 120, and secured therein by receiving the securing means in the corresponding mounting holes 240, 340 of the printed circuit board 200 and the reflector unit 300, respectively. The printed circuit board 200 may further include at least one light source 220 mounted at predefined location on the substrate 202. Preferably, plurality of light sources 220 may be arranged on the substrate 202 in a predefined configuration as per the functional requirements of the lighting device 100. The light sources 220 provided on the printed circuit board 200 may correspond to the reflective portions 320 of the reflector unit 300. The light sources 220 may be arranged in such a way that when the reflector unit 300 is assembled on the printed circuit board 200, the light from the light sources 220 may be efficiently reflected by the reflective portions 320 to emit desired light beam pattern through the optical lens unit 140. The printed circuit board 200 may further include at least one reference mark 260 provided at a predefined location on the substrate 202 of the printed circuit board 200. Preferably, plurality of reference marks 260 may be provided on the substrate 202 of the printed circuit board 200. The reference mark(s) 260 may be provided at predefined location(s) and in predefined orientation(s) with respect to at least one of the light sources 220. Advantageously, the plurality of reference marks 260 may correspond to the positioning holes 360 of the reflector unit 300. So, desired positioning of the reflective portions 320 of the reflector unit 300 with the light sources 220 of the printed circuit board 200 may be achieved by properly aligning the reference marks 260 of the printed circuit board 200 with corresponding positioning holes 360 of the reflector unit 300. Further, relative positioning between the light source(s) 220 and the reference mark(s) 260 may correspond to relative positioning between the positioning hole(s) 360 and the reflective portion(s) 320 of the reflector unit 300.

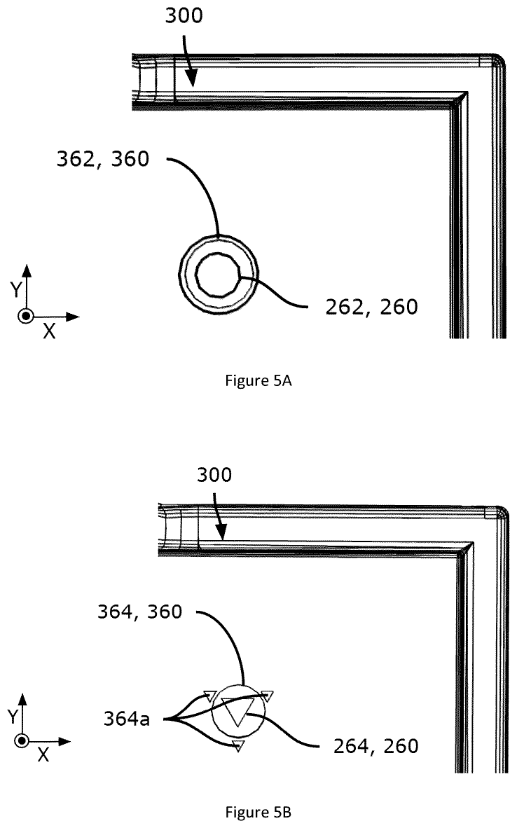

FIG. 4A shows top view of a sub-assembly 400 of the reflector unit 300 and the printed circuit board 200. For assembling the reflector unit 300 on the printed circuit board 200, the reference mark(s) 260 of the printed circuit board 200 may be aligned with the corresponding positioning hole(s) 360 of the reflector unit 300 such that the reference mark(s) 260 may be visible from top side of the reflector unit 300. Therefore, proper positioning of the reflector unit 300 and the printed circuit board 200 may be confirmed when the reference mark(s) 260 is aligned with the corresponding positioning hole(s) 360 and may be verified from the top side of the reflector unit 300. It is to be understood that in the lighting device 100, the reflector unit 300 may be provided on bottom side of the printed circuit board 200 and the similar positioning arrangement of the reference mark(s) 260 and the positioning hole(s) 360 may be realized.

The alignment of the reference mark(s) 260 of the printed circuit board 200 with the positioning hole(s) 360 of the reflector unit 300 may be detected and verified by a detection unit 500 relative to the sub-assembly 400 from top side of the reflector unit 300, as shown in FIG. 4B. The detection unit 500 may include a camera 520 for capturing images/video of the sub-assembly 400 during assembling process. It is to be understood that the detection unit may include additional components needed for processing the images to determine the alignment between the reference mark 260 and the positioning hole 360. Alternatively, the alignment of the reference mark(s) 260 of the printed circuit board 200 with the positioning hole(s) 360 of the reflector unit 300 may be visually verified by an assembly personnel. The detection unit 500 may have predefined alignment configurations of the reference mark 260 and the positioning hole 360 which may be acceptable as a desired alignment of the reference mark 260 with the positioning hole 360. The detection unit 500 may determine misalignment if detected alignment deviates from the acceptable alignment configurations. In case a misalignment of at least one of the reference marks 260 is detected by the assembly personnel or by the camera 520, the reflector unit 300 may be readjusted by moving in X-Y plane and/or rotating about Z axis with respect to the printed circuit board 200 till the desired alignment of the reference mark(s) 260 with the corresponding positioning hole(s) 360 is achieved. The detection unit 500 may be able to detect the misalignment(s) between the reference mark(s) 260 and the positioning hole(s) 360, and may determine corrective relative movement and/or corrective relative rotation required between the printed circuit board 200 and the reflector unit 300 to achieve the desired alignment. The information about these corrective relative movement and/or corrective relative rotation may be displayed on suitable display unit (not shown) and/or may be supplied to a robotic workstation for automatically making the required adjustments to the relative positioning between the printed circuit board 200 and the reflector unit 300.

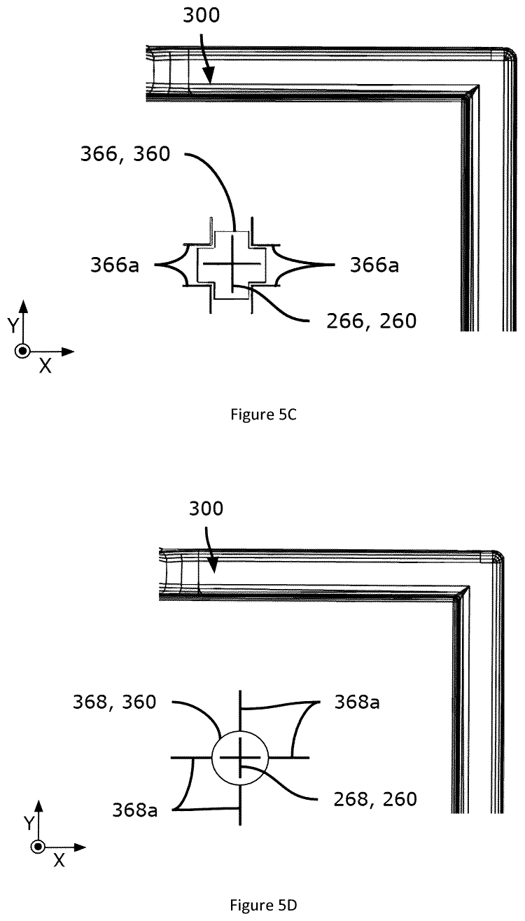

FIGS. 5A, 5B, 5C, and 5D show configurations of the reference marks 260 and corresponding positioning holes 360, according to different embodiments of the present invention. It is to be noted that in FIGS. 5A, 5B, 5C, and 5D, the printed circuit board 200 is hidden behind the reflector unit 300 and only a portion of printed circuit board 200 having the reference mark 260 is visible through the positioning hole 360. According to one embodiment, as shown in FIG. 5A, the reference mark 260 may include a circle 262 having a predefined diameter, and the positioning hole 360 may be a circular hole 362 of a predefined diameter. The diameter of the circle 262 may be less than the diameter of the circular hole 362 by a predefined value. For properly positioning the reflector unit 300 with the printed circuit board 200, the circle 262 may be aligned with the corresponding circular hole 362 such that the circle 262 is centered in the outline of circular hole 362. Preferably, a predefined offset of the circle 262 with respect to the outline of the circular hole 362 may be allowed. The camera 520 may detect the edge of the circular hole 362 and the circle 262 to determine whether the circular hole 362 and the circle 262 are aligned within a permissible limit of the offset. Preferably, at least two circles 262 may be provided at predefined locations on the printed circuit board 200 such that the desired positioning of the printed circuit board 200 with respect to the reflector unit 300 may be confirmed by aligning circles 262 with the corresponding circular holes 362 of the reflector unit 300. The detection unit 500 may determine that the positioning of the printed circuit board 200 with respect to the reflector unit 300 is not acceptable when at least one of the circles 262 is offset with respect to the outline of the corresponding circular hole 362 beyond permissible offset limit i.e. when at least one of the circles 262 is misaligned with the corresponding circular hole 362. It is to be noted that the permissible offset limit for the plurality of circles 262 may be same or different. In case of detecting misalignment, the detection unit 500 may determine the adjustments required between the printed circuit board 200 and the reflector unit 300 to properly align the circle(s) 262 with the corresponding circular hole(s) 362. The required adjustments may be determined in terms of relative movement in X-Y plane and/or relative rotation about the Z-axis, between the printed circuit board 200 and the reflector unit 300.

FIG. 5B shows the reference mark 260 and the corresponding positioning hole 360, according to an alternate embodiment of the present invention. The reference mark 260 may include a triangle 264 having predefined dimensions and the positioning hole 360 may be a circular hole 364 of a predefined diameter. The dimensions of the triangle 264 and diameter of the circular hole 364 may be adapted such that the triangle 264 may be entirely accommodated inside the outline of the circular hole 364. The reflector unit 300 may further include at least one alignment feature 364a provided on the periphery of the circular hole 364. Preferably, plurality of alignment features 364a may be provided around the circular hole 364. The alignment features 364a may be uniformly distributed around the circumference of the circular hole 364, as shown in FIG. 5B. The alignment features 364a may be provided on a top surface of the reflector unit 300 i.e. on a surface of the reflector unit 300 facing away from the printed circuit board 200 in the sub-assembly 400. Therefore, when viewed from top side of the sub-assembly 400, as depicted in FIG. 4B, the alignment features 364a may be visible or detectable by the detection unit 500. As shown in FIG. 5B, the alignment feature 364a may have a triangular shape. Preferably, the triangle 264 may be an equilateral triangle and three alignment features 364a may be provided uniformly around the circumference of the circular hole 364. For proper positioning of the printed circuit board 200 with the reflector unit 300, the triangle 264 may be aligned with the circular hole 364 such that the triangle 264 is positioned inside the outline of the circular hole 364 and the vertices of the triangle 264 may be pointing to the corresponding alignment feature 364a. It is to be noted that the alignment feature 364a may have any other shape such as circle, rectangle, or any other polygonal shape etc. The camera 520 may detect the edge of the circular hole 364, the alignment feature(s) 364a, and the triangle 264 to determine the alignment of the triangle 264 with the circular hole 364. The desired alignment between the triangle 264 and the circular hole 364 may be predefined in relation to the permissible clearance between the vertices of the triangle 264 and the outline of the circular hole 364, and permissible angular offset between the vertex of the triangle 264 and the corresponding alignment feature 364a. The detection unit 500 may determine that the positioning of the printed circuit board 200 with respect to the reflector unit 300 is not acceptable, when the triangle 264 is misaligned with the circular hole 364. The misalignment of the triangle 264 with the circular hole 364 may be determined when the clearance between at least one of the vertices of the triangle 264 is not within a predefined limit and/or the angular offset between the vertices of the triangle 264 and the alignment features 364a is beyond a predefined permissible offset limit. In case of detecting misalignment, the detection unit 500 may determine the adjustments required between the printed circuit board 200 and the reflector unit 300 to properly align the triangle 264 with the corresponding positioning hole 364. The required adjustment may be determined in terms of relative movement in X-Y plane and/or relative rotation about the Z-axis, between the printed circuit board 200 and the reflector unit 300. It is to be understood that the reference mark 260 may include any other polygonal shape and at least one of the vertices of the polygon may need to be aligned with corresponding alignment feature 364a to achieve proper angular positioning of the printed circuit board 200 with respect to the reflector unit 300.

FIG. 5C shows the reference mark 260 and the corresponding positioning hole 360, according to yet another alternate embodiment of the present invention. The reference mark 260 may include a cross mark 266 with two lines crossing each other at right angles. The cross mark 266 may be provided at a predefined location and in a predefined orientation with respect to at least one of the light sources 220 (refer FIG. 3). The positioning hole 360 may be a cross-shaped hole 366 having predefined dimensions. The dimensions of the cross-shaped hole 366 may be adapted such that the cross mark 266 may be accommodated in the outline of the cross-shaped hole 366, when viewed from top side of the sub assembly 400 as shown in FIG. 5C. The shape of the cross-shaped hole 366 may complement the cross mark 266. For proper positioning of the reflector unit 300 on the printed circuit board 200, the cross mark 266 may be aligned with the cross-shaped hole 364. The camera 520 may detect the edges of the cross-shaped hole 366 and the cross mark 266 to determine the alignment of the cross mark 266 with the cross-shaped hole 366. The desired alignment between the cross mark 266 and the cross-shaped hole 366 may be predefined in relation to the permissible clearance between the lines of the cross mark 266 and the outline of the corresponding edges of the cross-shaped hole 366, and permissible angular offset of the lines of the cross mark 266 with respect to the corresponding edges of the cross-shaped hole 366. Additionally, the reflector unit 300 may also include at least one alignment feature 366a provided on the periphery of the cross-shaped hole 366. Preferably, plurality of alignment features 366a may be provided on the periphery of the cross-shaped hole 366 and the alignment features 366a may have a predefined configuration with the edges of the cross-shaped hole as shown in FIG. 5C. In case of reflector unit 300 having the alignment features 366a, the desired alignment between the cross mark 266 and the cross-shaped hole 366 may be predefined in relation to the permissible clearance between the lines of the cross mark 266 and the corresponding line(s) of the alignment feature 366a, and permissible angular offset of the lines of the cross mark 266 with respect to the corresponding line(s) of the alignment feature 366a. The alignment features 366a may be provided on the top surface of the reflector unit 300 i.e. on the surface of the reflector unit 300 facing away from the printed circuit board 200 in the sub-assembly 400. Therefore, when viewed from top side of the sub-assembly 400, as depicted in FIG. 4B, the alignment features 366a may be visible or detectable by the camera 520. The detection unit 500 may determine that the positioning of the printed circuit board 200 with respect to the reflector unit 300 is not acceptable when the cross mark 266 is misaligned with the cross-shaped hole 366. The misalignment of the cross mark 266 with the cross-shaped hole 366 may be determined when the clearance between the lines of the cross mark 266 and the corresponding edges of the cross-shaped hole 366 or corresponding line(s) of the alignment feature 366a is/are not in a predefined limit and/or the angular offset of the lines of the cross mark 266 with respect to the outline of the corresponding edges of the cross-shaped hole 366 or with respect to the corresponding lines of the alignment features 366a is not within a predefined permissible limit. In case of detecting misalignment, the detection unit 500 may determine the adjustments required between the printed circuit board 200 and the reflector unit 300 to properly align the cross mark 266 with the corresponding cross-shaped hole 366. The required adjustments may be determined in terms of relative movement in X-Y plane and/or relative rotation about the Z-axis, between the printed circuit board 200 and the reflector unit 300.

FIG. 5D shows the reference mark 260 and the corresponding positioning hole 360, according to yet another alternate embodiment of the present invention. The reference mark 260 may include a cross mark 268 with two lines crossing each other at right angles. The cross mark 268 may be provided at a predefined location and in a predefined orientation with respect to at least one of the light sources 220 (refer FIG. 3). The positioning hole 360 may be a circular hole 368 having predefined diameter. The diameter of the circular hole 368 may be adapted such that the cross mark 268 may be accommodated in the outline of the circular hole 368, when viewed from top side of the sub assembly 400 as shown in FIG. 5D. The reflector unit 300 may further include at least one alignment feature 368a provided on the periphery of the circular hole 368. Preferably, plurality of alignment features 368a may be provided around the circular hole 368. The alignment features 368a may be provided on a top surface of the reflector unit 300 i.e. on a surface of the reflector unit 300 facing away from the printed circuit board 200 in the sub-assembly 400. Therefore, when viewed from top side of the sub-assembly 400, as depicted in FIG. 4B, the alignment features 368a may be visible or detectable by the camera 500. The alignment feature 368a may include line(s) extending in a direction normal to the outline of the circular hole 368, as shown in FIG. 5D. Preferably, plurality of alignment features 368a may be provided uniformly around the periphery of the positioning hole 368. For proper positioning of the printed circuit board 200 with respect to the reflector unit 300, the cross mark 268 may be aligned with the circular hole 368 such that the cross mark 268 is positioned in the outline of the circular hole 368 and lines of the cross mark 268 are substantially co-linear with the corresponding line of the alignment feature 368a. Angular offset between the line of the cross mark 268 and the corresponding line of the alignment feature 368a may be allowed in a permissible limit. The camera 520 may detect the edge of the circular hole 368, the alignment feature(s) 368a, and the cross mark 268 to determine the alignment of the cross mark 268 with the circular hole 368. The desired alignment between the cross mark 268 and the circular hole 368 may be predefined in relation to the permissible relative positioning of the cross mark 268 inside the outline of the circular hole 368 and/or permissible angular offset between the lines of the cross mark 268 and the corresponding lines of the alignment feature 368a. The detection unit 500 may determine that the positioning of the printed circuit board 200 with respect to the reflector unit 300 is not acceptable when the cross mark 268 is misaligned with the circular hole 368. The misalignment of the cross mark 268 with the circular hole 368 may be determined when the relative position of the cross mark 268 with the outline of the circular hole 368 is not within a predefined limit and/or the angular offset of the lines of the cross mark 268 with the lines of the alignment features 368a is beyond a predefined permissible offset. In case of detecting misalignment, the detection unit 500 may determine the adjustments required between the printed circuit board 200 and the reflector unit 300 to properly align the cross mark 268 with the corresponding positioning hole 368. The required adjustment may be determined in terms of relative movement in X-Y plane and/or relative rotation about the Z-axis, between the printed circuit board 200 and the reflector unit 300. It is to be understood that the alignment feature 364a of above disclosed embodiment corresponding to FIG. 5B, may be used instead of the alignment feature 368a of this embodiment such that the triangles of the alignment feature 364a may correspond to the lines of the cross mark 268.

The printed circuit board 200 may include any suitable combination of the reference marks 260, 262, 264, 266, 268 disclosed in abovementioned embodiments. The reflector unit 300 may include corresponding combination of the positioning holes 360, 362, 364, 366, 368 disclosed in abovementioned embodiments.

It is to be noted that the reference mark 260, 262, 264, 266, 268 according any of abovementioned embodiments, may be formed on the printed circuit board 200 by any of the suitable means. Preferably, the reference mark 260, 262, 264, 266, 268 may be formed by laser printing, screen printing, painting, embossing, or pasting a sticker. Alternatively, the reference mark 260, 262, 264, 266, 268 may be integrally formed on the substrate 202 of the printed circuit board 200. Similarly, the alignment feature(s) 364a, 366a, 368a may be formed on the reflector unit 300 by laser printing, screen printing, painting, embossing, or pasting a sticker. Alternatively, the the alignment feature(s) 364a, 366a, 368a may be integrally formed on the reflector unit 300. It is to be noted that any other suitable means may be used to form the reference mark 260, 262, 264, 266, 268 on the printed circuit board 200 and the alignment feature(s) 364a, 366a, 368a on the reflector unit 300.

Advantageously, the reference mark 260, 262, 264, 266, 268 may have a color and/or texture distinguishable from color and/or texture of the printed circuit board 200. This difference between the colors and/or textures of the reference mark 260, 262, 264, 266, 268 and the printed circuit board 200 may improve accuracy of detection of the reference mark 260, 262, 264, 266, 268 by the camera 520. Further, the reflector unit 300, more specifically the top surface of the reflector unit 300 may have a color, at least near the positioning hole 360, 362, 364, 366, 368, that may be distinguishable from color of the printed circuit board 200. This difference between the colors of the printed circuit board 200 and the reflector unit 300 may improve detection of the edge(s) of the positioning hole 360, 362, 364, 366, 368 by the camera 520. Moreover, the alignment feature(s) 364a, 366a, 368a may have a color and/or texture distinguishable from the color and/or texture of the top surface of the reflector unit 300 to improve detection of the alignment feature(s) 364a, 366a, 368a by the camera 520. It is to be noted that the top surface of the reflector unit 300 refers to the surface of the reflector unit 300 facing away from the printed circuit board 200 or the surface of the reflector unit 300 facing towards the camera 520.

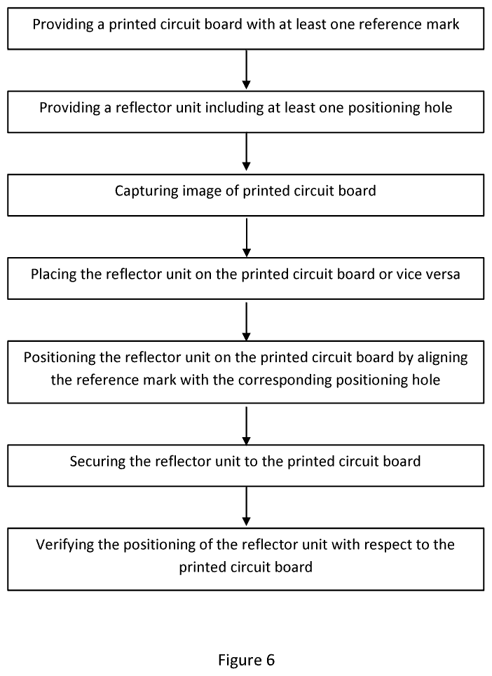

FIG. 6 shows a flowchart depicting a method of assembling the reflector unit 300 on a printed circuit board 200, according to an embodiment of the present invention. The method may be used for assembling the reflector unit 300 having the positioning hole(s) 360, 362, 364, 366, 368 according to any of abovementioned embodiments on the printed circuit board 200 having corresponding reference mark(s) 260, 262, 264, 266, 268. The method may include providing the printed circuit board 200 including at least one reference mark 260, 262, 264, 266, 268 according to any of abovementioned embodiments. The reference mark 260, 262, 264, 266, 268 may be provided at a predefined location and orientation with respect to at least one light source 220. The printed circuit board 200 may include plurality of reference marks 260, 262, 264, 266, 268 provided at predefined locations and orientations relative to the plurality of light sources 220. It is to be noted that the printed circuit board 200 may be mounted on the heatsink structure 120 or held in a fixture on an assembly station. The method may further include providing a reflector unit 300 including at least one positioning hole 360, 362, 364, 366, 368 according to any of abovementioned embodiments such that the positioning hole 360, 362, 364, 366, 368 complements the reference mark 260, 262, 264, 266, 268 of the printed circuit board 200. The positioning hole 360, 362, 364, 366, 368 may be formed at a predefined location and orientation with respect to at least one reflective portion 320 of the reflector unit 300. The reflector unit 300 may include plurality of positioning holes 360, 362, 364, 366, 368 formed at predefined locations and orientations relative to the plurality of reflective portions 320. The method may further include placing the reflector unit 300 on the printed circuit board 200. Alternatively, the reflector unit 300 may be held in fixture on the assembly station and the printed circuit board 200 may be placed on the reflective unit 300. The method may further include positioning the reflector unit 300 on the printed circuit board 200 by aligning the reference mark 260, 262, 264, 266, 268 with the corresponding positioning hole 360, 362, 364, 366, 368. The desired/acceptable alignment configuration of the reference mark 260, 262, 264, 266, 268 with the corresponding positioning holes 360, 362, 364, 366, 368 may be predefined as disclosed in the previous embodiments.

Advantageously, positioning of the reflector unit 300 on the printed circuit board 200 may include detecting and monitoring the alignment of the at least one reference mark 260, 262, 264, 266, 268 with the corresponding positioning hole 360, 362, 364, 366, 368 by the detection unit 500. The camera 520 of the detection unit 500 may detect the alignment of the reference mark 260, 262, 264, 266, 268 with the corresponding positioning hole 360, 362, 364, 366, 368, and compare it with a desired alignment configuration to determine whether the detected alignment is acceptable or not. It is to be understood that the printed circuit board 200 may include any combination of the reference marks 260, 262, 264, 266, 268 and the reflector unit 300 may include corresponding combination of the positioning holes 360, 362, 364, 366, 368. Thus, the desired alignment configuration may be defined for each pair of the reference mark 260, 262, 264, 266, 268 and the corresponding positioning hole 360, 362, 364, 366, 368. The desired alignment configuration may include acceptable/permissible clearance between the reference mark 260, 262, 264, 266, 268, and edge(s) of the corresponding positioning hole 360, 362, 364, 366, 368 or the corresponding alignment feature 366a. The desired alignment configuration may also include acceptable/permissible angular alignment or angular orientation or angular offset between the reference mark 260, 262, 264, 266, 268 and the corresponding alignment features 364a, 366a, 368a of the positioning hole 360, 362, 364, 366, 368. When detection unit 500 determines that the detected alignment of the reference mark 260, 262, 264, 266, 268 with the corresponding positioning hole 360, 362, 364, 366, 368 does not meet the desired alignment configuration, the relative position and/or orientation of the reflector unit 300 with respect to the printed circuit board 200 may be readjusted till the desired alignment of the reference mark 260, 262, 264, 266, 268 with the corresponding positioning hole 360, 362, 364, 366, 368 is achieved and verified by the detection unit 500. Advantageously, the detection unit 500 may be equipped with the feature of determining the corrective relative movements and/or corrective relative rotation about Z axis, between the reflector unit 300 and the printed circuit board 200 that may be required to meet the desired alignment. The readjustment between the reflector unit 300 and the printed circuit board 200 may be automatically done by the suitable means. Once the desired alignment between the reference mark(s) 260, 262, 264, 266, 268 and the corresponding positioning hole(s) 360, 362, 364, 366, 368 is verified by the detection unit 500, the reflector unit 300 may be secured to the printed circuit board 200 to provide the sub-assembly 400.

Additionally, the detection unit 500 may also verify the alignment between the reference mark(s) 260, 262, 264, 266, 268 and the corresponding positioning hole(s) 360, 362, 364, 366, 368, after the reflector unit 300 is secured to the printed circuit board 200, to confirm the desired positioning between the reflector unit 300 and the printed circuit board 200.

It is to be understood that the method according to the present invention may also include other known/suitable activities that may be required for assembling the reflector unit 300 with the printed circuit board 200.

The invention shall not, however, be limited to the means and configurations described and illustrated herein, and shall also extend to any equivalent means or configuration described and illustrated herein, and to any technical combination operating such means.

### LIST OF REFERENCE SIGNS

100 Lighting device
120 Heatsink structure
140 Optical Lens unit
200 Printed Circuit Board
220 Light source
240 Mounting hole
260 Reference mark
262 Circle
264 Triangle
266, 268 Cross mark
300 Reflector unit
320 Reflective portion
340 Mounting hole
360, 362, 364, 366, 368 Positioning hole
362, 364, 368 Circular hole
366 Cross-shaped hole
364a, 366a, 368a Alignment feature
400 Sub-assembly
500 Detection unit
520 Camera

1. A printed circuit board, comprising:
a substrate;
at least one light source mounted on the substrate; and
at least one reference mark provided on the substrate at a predefined location and orientation with respect to the at least one light source,
wherein the at least one reference mark is configured to be aligned with a corresponding positioning hole formed on a reflector unit and visible thru the reflector when the reflector is positioned on the substrate.

2. The printed circuit board according to claim 1, wherein the at least one reference mark includes a circle having a predefined diameter.

3. The printed circuit board according to claim 1, wherein the at least one reference mark includes at least one line or a polygon having predefined dimensions.

4. The printed circuit board according to claim 1, wherein the at least one reference mark is provided on the substrate by laser printing, screen printing, painting, embossing, or pasting a sticker.

5. The printed circuit board according to claim 1, wherein the at least one reference mark is integrally formed on the substrate.

6. The printed circuit board according to claim 1, wherein the at least one reference mark has a predefined color.

7. A sub-assembly for a lighting device, the sub-assembly comprising:
a reflector unit having at least one reflective portion; and
a printed circuit board including at least one light source, the reflector unit being mounted on the printed circuit board,
wherein the printed circuit board includes at least one reference mark provided at a predefined location and orientation with respect to the at least one light source,
wherein the reflector unit includes at least one positioning hole formed at a predefined location and orientation with respect to the at least one reflective portion, and
wherein the at least one positioning hole of the reflector unit corresponds to the at least one reference mark of the printed circuit board, with the at least one reference mark being visible thru the reflector when the reflector is mounted on the printed circuit board.

8. The sub-assembly according to claim 7, wherein the at least one reference mark is aligned with the corresponding positioning hole of the reflector unit.

9. The sub-assembly according to claim 7, wherein the at least one reference mark includes a circle having a predefined diameter.

10. The sub-assembly according to claim 7, wherein the at least one reference mark includes at least one line or a polygon having a predefined dimensions.

11. The sub-assembly according to claim 10, wherein the reflector unit further includes at least one alignment feature provided on the periphery of the positioning hole.

12. The sub-assembly according to claim 11, wherein the at least one alignment feature complements the at least one reference mark provided on the printed circuit board.

13. The sub-assembly according to claim 11, wherein the at least one alignment feature is provided on the reflector unit by laser printing, screen printing, painting, embossing, pasting a sticker, or integrally forming on the reflector unit.

14. The sub-assembly according to claim 11, wherein the at least one alignment feature has a predefined color.

15. The sub-assembly according to claim 7, wherein the at least one reference mark is provided on the substrate by laser printing, screen printing, painting, embossing, pasting a sticker, or integrally forming with the substrate.

16. The sub-assembly according to claim 7, wherein the at least one reference mark has a predefined color.

17. A method of assembling a reflector unit on a printed circuit board, the method comprising:
providing a printed circuit board including at least one reference mark provided at a predefined location and orientation with respect to at least one light source;
providing a reflector unit including at least one positioning hole formed at a predefined location and orientation with respect to at least one reflective portion;
placing the reflector unit on the printed circuit board or vice versa;
positioning the reflector unit on the printed circuit board by aligning the reference mark with the corresponding positioning hole; and
securing the reflector unit to the printed circuit board.

18. The method according to claim 17, wherein positioning the reflector unit on the printed circuit board includes detecting and monitoring alignment of the at least one reference mark with the corresponding positioning hole by a detection unit.

19. The method according to claim 18, wherein positioning the reflector unit on the printed circuit board includes readjusting the relative position and/or orientation of the reflector unit with respect to the printed circuit board till the desired alignment of the reference mark with the corresponding positioning hole is achieved and verified by the detection unit.

20. The method according to claim 19, wherein positioning the reflector unit on the printed circuit board includes capturing an image of the printed circuit board before placing the reflector unit on the printed circuit board, for detecting the relative position and orientation of the reference mark with respect to the at least one light source to determine the desired alignment of the reference mark with the positioning hole.
